(19) United States
(12) Patent Application Publication
(10) Pub. No.: US 2008/0231254 A1
(43) Pub. Date: Sep. 25, 2008

(54) SPECTRUM ANALYZER, SPECTRUM ANALYSIS METHOD AND RECORDING MEDIUM

(75) Inventors: Eiji Kanoh, Tokyo (JP); Makoto Nakanishi, Tokyo (JP)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ADVANTEST CORPORATION, Tokyo (JP)

(21) Appl. No.: 11/864,925

(22) Filed: Sep. 29, 2007

(30) Foreign Application Priority Data
Oct. 3, 2006 (JP) 2006-272153

(51) Int. Cl. G01R 23/00

(52) U.S. Cl. 324/76.19

(57) ABSTRACT

A spectrum analyzer that measures a signal component for every frequency of an input signal includes a local signal generating section generating a local signal having a designated frequency, a multiplying section outputting a synthesized signal obtained by multiplying the local signal with the input signal, a band-pass filter through which a signal component having a prescribed frequency band of the synthesized signal is passed, an A-D conversion section outputting a digital output signal obtained by sampling and digitalizing the passed signal component, a spectrum generation section that passes a signal component within a measured frequency range of the input signal through the band-pass filter and generates a first frequency spectrum based on the digital output signal acquired from the signal component passed through the band-pass filter, and an elimination section generating a frequency spectrum free of noise based on the first frequency spectrum generated by the spectrum generation section.

### CROSS REFERENCE TO RELATED APPLICATION

The present application claims priority from a Japanese Patent Application No. 2006-272153 filed on Oct. 3, 2006, the contents of which are incorporated herein by reference.

### BACKGROUND

1. Technical Field

The present invention relates to a spectrum analyzer, a spectrum analysis method, and a recording medium and, more particularly, the present invention relates to a spectrum analyzer, a spectrum analysis method, and a recording medium for measuring a signal component for every frequency of an input signal.

2. Related Art

As an apparatus for analyzing a frequency of a signal, a spectrum analyzer is known as, for example, in Japanese Patent Application Publication No. 2001-272425 and International Publication Pamphlet No. 2002/029426. The spectrum analyzer multiplies an input signal, which is the signal to be measured, with a local signal, which has a frequency changed within a prescribed frequency range, to generate an IF signal. A prescribed frequency band component of the generated IF signal is then passed through a band-pass filter by the spectrum analyzer. Then, the spectrum analyzer samples the signal component passed through the band-pass filter and generates a frequency spectrum of the input signal based on data acquired from the sampling.

Furthermore, a PLL (Phase Locked Loop) circuit using a fractional frequency divider is known. The PLL circuit using the fractional frequency divider can set an output frequency to be a frequency abotained by multiplying a reference clock by a coefficient having fractional precision.

In a case where the PLL circuit using the fractional frequency divider is employed as a local signal generator in the spectrum analyzer, the frequency analyzing ability of the spectrum analyzer can be increased because the frequency of the local signal can be changed more precisely than the reference frequency. However, the fractional frequency divider generates fractional spurious, which is a signal including a frequency corresponding to a phase difference between the reference clock and the local signal. Accordingly, the spectrum analyzer employing the PLL circuit using the fractional frequency divider as a local signal generator outputs a frequency spectrum including noise caused by the fractional spurious. Furthermore, in such a spectrum analyzer, there is a case where noise caused by mixing of the signal passed through the band-pass filter with an operational clock of the circuit is included in the measurement result.

### SUMMARY

Therefore, it is an object of an aspect of the present invention to provide a spectrum analyzer, a spectrum analysis method, and a recording medium that are capable of overcoming the above drawbacks accompanying the related art. The above and other objects can be achieved by combinations described in the independent claims. The dependent claims define further advantageous and exemplary combinations of the present invention.

According to a first aspect related to the innovations herein, one exemplary apparatus may include a spectrum analyzer that measures a signal component for every frequency of an input signal. The spectrum analyzer includes a local signal generating section that generates a local signal having a designated frequency, a multiplying section that outputs a synthesized signal obtained by multiplying the local signal with the input signal, a band-pass filter through which a signal component having a prescribed frequency band of the synthesized signal is passed, an A-D conversion section that outputs a digital output signal obtained by sampling and digitalizing the signal component passed through the band-pass filter, a spectrum generation section that passes a signal component within a measured frequency range of the input signal through the band-pass filter and generates a first frequency spectrum based on the digital output signal acquired from the signal component passed through the band-pass filter, and an elimination section that generates a frequency spectrum free of noise based on the first frequency spectrum generated by the spectrum generation section.

Furthermore, according to a second aspect related to the innovations herein, one exemplary method may include a spectrum analysis method that measures a signal component for every frequency of an input signal using a spectrum analyzer. The spectrum analysis method includes generating a local signal having a designated frequency, outputting a synthesized signal obtained by multiplying the local signal with the input signal, passing a signal component having a prescribed frequency band of the synthesized signal, outputting a digital output signal obtained by sampling and digitalizing the passed signal component, passing a signal component within a measured frequency range of the input signal and generating a first frequency spectrum based on the digital output signal acquired from the passed signal component, and generating a frequency spectrum free of noise based on the generated first frequency spectrum.

Furthermore, according to a third aspect related to the innovations herein, one exemplary medium may include a recording medium that stores thereon a program controlling through a computer a spectrum analyzer that measures a signal component for every frequency of an input signal. The recording medium stores a program that makes the spectrum analyzer function as a local signal generating section that generates a local signal having a designated frequency, a multiplying section that outputs a synthesized signal obtained by multiplying the local signal with the input signal, a band-pass filter through which a signal component having a prescribed frequency band of the synthesized signal is passed, an A-D conversion section that outputs a digital output signal obtained by sampling and digitalizing the signal component passed through the band-pass filter, a spectrum generation section that passes a signal component within a measured frequency range of the input signal through the band-pass filter and generates a first frequency spectrum based on the digital output signal acquired from the signal component passed through the band-pass filter, and an elimination section that generates a frequency spectrum free of noise based on the first frequency spectrum generated by the spectrum generation section.

Furthermore, according to a fourth aspect related to the innovations herein, one exemplary apparatus may include a spectrum analyzer that measures a signal component for every frequency of an input signal. The spectrum analyzer includes a local signal generating section that generates a local signal having a designated frequency, a multiplying section that outputs a synthesized signal obtained by multiplying the local signal with the input signal, a band-pass filter through which a signal component having a prescribed frequency band of the synthesized signal is passed, an A-D conversion section that outputs a digital output signal obtained by sampling and digitalizing the signal component passed through the band-pass filter, and a spectrum generation section that passes a signal component within a measured frequency range of the input signal through the band-pass filter and generates a first frequency spectrum based on the digital output signal acquired from the signal component passed through the band-pass filter. The local signal generating section of the spectrum analyzer includes an oscillator that generates a local signal having a frequency according to a control signal, a frequency divider that sets a switching ratio for switching between a period of frequency-dividing with a first frequency-dividing ratio having an integer value and a period of frequency-dividing with a second frequency-dividing ratio having an integer value according to the frequency of the local signal and outputs a frequency-divided signal obtained by frequency-dividing the local signal while switching between the first frequency-dividing ratio and the second frequency-dividing ratio according to the switching ratio, and a phase detector that outputs the control signal according to a phase difference between the frequency-divided signal and a reference clock. The spectrum generation section of the spectrum analyzer is provided with a local signal generating section configured in a manner to generate a local signal having a frequency such that the frequency difference between a first frequency, which is obtained by multiplying the reference frequency of the reference clock with the first frequency-dividing ratio, and a second frequency, which is obtained by multiplying the reference frequency with the second frequency-dividing ratio, is not less than or equal to a predetermined threshold value.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 shows a configuration of a spectrum analyzer 10 according to an embodiment of the present invention.

FIG. 2 shows an example of a measurement result output screen 62.

FIG. 3(A) shows an example of a first frequency spectrum, and FIG. 3(B) shows an example of a second frequency spectrum.

FIG. 4 shows a strength of fractional spurious in a local signal and also shows a range of local frequencies free of the fractional spurious.

FIG. 5 shows a configuration of a spectrum analyzer 10 according to a first modification of the present embodiment.

FIG. 6 shows a configuration of a spectrum analyzer 10 according to a second modification of the present embodiment.

FIG. 7 shows an example of noise generated by fractional spurious.

FIG. 8 shows a configuration of a spectrum analyzer 10 according to a third modification of the present embodiment.

FIG. 9 shows an example of a measurement result output screen 62 before noise elimination.

FIG. 10 shows an example of the measurement result output screen 62 after noise elimination.

FIG. 11 shows an example of a hardware configuration of a computer 1900 according to the present embodiment.

### DESCRIPTION OF EXEMPLARY EMBODIMENTS

Hereinafter, an embodiment of the present invention will be described. The embodiment does not limit the invention according to the claims, and all the combinations of the features described in the embodiment are not necessarily essential to means provided by aspects of the invention.

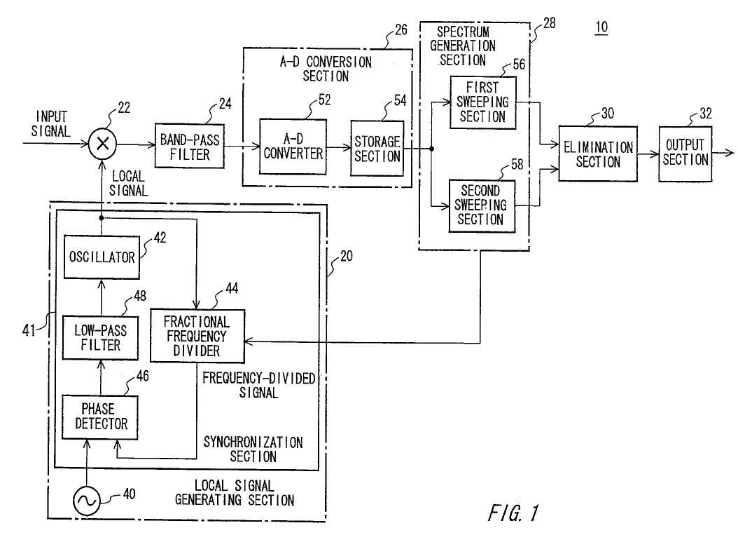

FIG. 1 shows a configuration of a spectrum analyzer 10 according to an embodiment of the present invention. The spectrum analyzer 10 measures a signal component for every frequency of an input signal and is provided with a local signal generating section 20, a multiplying section 22, a band-pass filter 24, an A-D conversion section 26, a spectrum generation section 28, an elimination section 30, and an output section 32. The spectrum analyzer 10, based on a measurement result, outputs a spectrum frequency expressing a signal level for each frequency within a measured frequency range of the input signal.

The local signal generating section 20 generates a local signal having a designated frequency. The local signal generating section 20 includes a reference clock generation section 40 and a synchronization section 41. The reference clock generation section 40 generates a reference clock having a reference frequency. The synchronization section 41 outputs the local signal having a local frequency multiple decimal points more precise than the reference frequency of the reference clock. For example, in a case where N is an integer greater than or equal to one and F is a value greater than or equal to zero but less than or equal to one, the synchronization section 41 may output, as one example, a local signal having a local frequency that is (N+F) times the reference frequency.

The synchronization section 41 may include an oscillator 42, a fractional frequency divider 44, a phase detector 46, and a low-pass filter 48. The oscillator 42 generates a local signal having a frequency corresponding to a control signal.

The fractional frequency divider 44 is an example of a frequency divider according to the present invention. The fractional frequency divider 44 designates a first frequency-dividing ratio having an integer value, a second frequency-dividing ratio having an integer value, and a switching ratio between the period for frequency-dividing with the first frequency-dividing ratio having an integer value and the period for frequency-dividing with the second frequency-dividing ratio having an integer value according to the frequency of the local signal to be generated. For example, the fractional frequency divider 44 may designate N as the first frequency-dividing ratio (N is an integer greater than or equal to one), (N+1) as the second frequency-dividing ratio, and F as the switching ratio (F is a value greater than or equal to zero but less than or equal to one). The fractional frequency divider 44 may frequency-divide the local signal while switching between the first frequency-dividing ratio and the second frequency-dividing ratio according to the designated switching ratio. For example, the fractional frequency divider 44 may frequency-divide the local signal while switching between the period for frequency-dividing with the first frequency-dividing ratio N and the period for frequency-dividing with the second frequency-dividing ratio (N+1) at a ratio of F:(1−F).

Therefore, when averaged over time, the fractional frequency divider 44 can frequency-divide the local signal with a frequency-dividing ratio, which is a fractional ratio corresponding to the switching ratio between the first frequency-dividing ratio having an integer value and the second frequency-dividing ratio having an integer value. In a case where, for example, the first frequency-dividing ratio is designated as N, the second frequency-dividing ratio is designated as (N+1), and the switching ratio is designated as F, the fractional frequency divider 44 can frequency-divide the local signal with a frequency-dividing ratio of (N+F) when averaged. The fractional frequency divider 44 then outputs a frequency-divided signal, which is the frequency-divided local signal. For example, a first frequency divider with a fixed frequency-dividing ratio having an integer value may be included in a front portion of the fractional frequency divider 44 and a second frequency divider that can frequency-divide the output of the first frequency divider with a fractional frequency-dividing ratio may be included in a back portion of the fractional frequency divider 44.

The phase detector 46 detects a phase difference between the frequency-divided signal and the reference clock. The phase detector 46 then outputs a control signal corresponding to the detected phase difference. The low-pass filter 48 low-pass filters the control signal output by the phase detector 46 and outputs the low-pass filtered signal to the oscillator 42. For example, the low-pass filter 48 may change a time constant according to the switching ratio designated by the fractional frequency divider 44. For example, in a case where the fractional spurious generated according to the switching ratio of the low-pass filter 48 is large, the fractional frequency divider 44 may increase the time constant and, in a case where the fractional spurious is small, the low-pass filter 48 may decrease the time constant. Therefore, in the case of a switching ratio causing a large fractional spurious, the low-pass filter 48 can decrease the fractional spurious and, in a case of a switching ratio causing a small fractional spurious, the low-pass filter 48 can respond more quickly.

Through the local signal generating section 20 having such a configuration, a local signal having a frequency X times (here, X is a value expressing fractional precision) the reference frequency of the reference clock can be output. Furthermore, the local signal generating section 20 can output a local signal having a frequency set by the first frequency-dividing ratio, the second frequency-dividing ratio, and the switching ratio. In other words, the local signal generating section 20 can output a local signal having a frequency according to a switching ratio between a first frequency, which is the reference frequency of the reference clock multiplied by the first frequency-dividing ratio, and a second frequency, which is the reference frequency multiplied by the second frequency-dividing ratio. For example, in a case where the first frequency-dividing ratio is designated as N, the second frequency-dividing ratio is designated as (N+1), and the switching ratio is designated as F, the local signal generating section 20 can output a local signal having a frequency (N+F) times the reference frequency.

A PLL circuit operating with an output local signal having a frequency of 2-4 GHz, a reference clock having a reference frequency of 10 MHz, and a frequency-dividing ratio having an integer multiplication factor of 200-400 outputs a local signal at 10 MHz intervals. In other words, such a PLL circuit outputs local signals having frequencies of 2 GHz (frequency-dividing ratio 200), 2.01 GHz (frequency-dividing ratio 201), 2.02 GHz (frequency-dividing ratio 202), . . . , 3.99 GHz (frequency-dividing ratio 399), and 4 GHz (frequency-dividing ratio 400). As opposed to this, the local signal generating section 20 including the fractional frequency divider 44 can control more precise fractional resolutions. For example, the local signal generating section 20 including the fractional frequency divider 44 that can set a frequency-dividing ratio of 1/4096 can output local signals having frequencies of 2 GHz (frequency-dividing ratio 200+0), 2.000002441 GHz (frequency-dividing ratio 200+1/4096), 2.000004882 GHz (frequency-dividing ratio 200+2/4096), . . . , 2.01 GHz (frequency-dividing ratio 200+0), 2.010002441 GHz (frequency-dividing ratio 200+1/4096), . . . , and 4 GHz (frequency-dividing ratio 400+0).

The multiplying section 22 outputs a synthesized signal, which is obtained by multiplying the local signal with the input signal. Therefore, the multiplying section 22 can output the synthesized signal, which is the input signal having a frequency shifted by an amount of the local frequency. The signal component having the prescribed frequency band of the synthesized signal is then passed through the band-pass filter 24. Therefore, the signal component having a frequency set by the local frequency in the input signal can be passed through the band-pass filter 24.

The A-D conversion section 26 samples the signal component passed through the band-pass filter 24, digitalizes the sampled signal, and outputs the digital output signal. The A-D conversion section 26 may include, for example, an A-D converter 52 and a storage section 54. The A-D converter 52 outputs a digital output signal, which is a sample of the signal passed through the band-pass filter 24 at a prescribed sampling frequency. The storage section 54 sequentially stores the digital output signals output from the A-D converter 52.

The spectrum generation section 28 controls the local frequency of the local signal generated by the local signal generating section 20 and passes the signal component within a measured frequency range of the input signal through the band-pass filter 24. The spectrum generation section 28 then generates a first frequency spectrum based on the digital output signal acquired from the signal component passed through the band-pass filter 24. Next, the spectrum generation section 28 controls the local signal generated by the local signal generating section 20 to set the local frequency thereof to be different from the local frequency during generation of the first frequency spectrum and passes the signal component within the measured frequency range of the input signal through the band-pass filter 24. The spectrum generation section 28 then generates a second frequency spectrum based on the digital output signal acquired from the signal component passed through the band-pass filter 24.

In the present embodiment, the spectrum generation section 28 outputs the local signal having the prescribed frequency from the local signal generating section 20 by designating the first frequency-dividing ratio, the second frequency-dividing ratio, and the switching ratio for the local signal generating section 20. In other words, the spectrum generation section 28 outputs the local signal having the prescribed frequency from the oscillator 42 by designating the first frequency-dividing ratio, the second frequency-dividing ratio, and the switching ratio for the fractional frequency divider 44.

Furthermore, the spectrum generation section 28 sweeps the input signal in a direction of the frequency by sequentially and discretely changing the frequencies of the local signal, passes the signal component of each frequency within the measured frequency range of the input signal through the band-pass filter 24, and samples the signal component passed through the band-pass filter 24 using the A-D conversion section 26. The spectrum generation section 28 then generates the frequency spectrum based on the digital output signal of the signal component of each frequency within a measured frequency range sampled by the A-D conversion section 26.

Here, by using the fractional frequency divider 44, the local signal generating section 20 can output the local signal including fractional spurious at a frequency according to the switching ratio of the fractional frequency divider 44. In other words, the local signal generating section 20 can output the local signal including fractional spurious at a frequency according to both a frequency that is a product of the reference frequency of the reference clock multiplied by the first frequency-dividing ratio and a difference between the aforementioned frequency and the frequency of the local signal. As a result, the spectrum generation section 28 can output the frequency spectrum including noise caused by the fractional spurious at a prescribed frequency place.

The spectrum generation section 28 described above includes a first sweeping section 56 and a second sweeping section 58. The first sweeping section 56 sequentially and discretely changes the frequencies of the local signal, passes the signal component of each frequency within the measured frequency range of the input signal through the band-pass filter 24, and generates a first frequency spectrum based on the digital output signal acquired from the signal component passed through the band-pass filter 24. The second sweeping section 58 sequentially and discretely changes the frequencies of the local signal with a switching ratio different from that used during generation of the first frequency spectrum, passes the signal component of each frequency within the measured frequency range of the input signal through the band-pass filter 24, and generates a second frequency spectrum based on the digital output signal acquired from the signal component passed through the band-pass filter 24. In other words, the second sweeping section 58 sequentially and discretely changes the frequencies of the local signal with a frequency different from that used during generation of the first frequency spectrum, passes the signal component of each frequency within the measured frequency range of the input signal through the band-pass filter 24, and generates the second frequency spectrum based on the digital output signal acquired from the signal component passed through the band-pass filter 24.

In the manner described above, the spectrum generation section 28 performs two sweeps of the input signal with different switching ratios. In other words, the spectrum generation section 28 sequentially generates local signals having different frequencies and then uses these local signals to sweep the input signal twice. Therefore, the spectrum generation section 28 can generate two frequency spectrums having different frequencies in which the noise caused by the fractional spurious is generated.

The elimination section 30 generates the frequency spectrum free of noise based on the first frequency spectrum generated by the first sweeping section 56 and the second frequency spectrum generated by the second sweeping section 58. For example, the elimination section 30 may generate the frequency spectrum free of noise based on a smaller value from among signal components having generally the same frequency in the first frequency spectrum and the second frequency spectrum. For example, the elimination section 30 may generate the frequency spectrum free of noise caused by the fractional spurious by comparing the first frequency spectrum and the second frequency spectrum having different frequencies in which the noise caused by the fractional spurious is generated.

The output section 32 acquires the frequency spectrum free of noise from the elimination section 30 and then outputs the frequency spectrum free of noise. For example, the output section 32 may display the frequency spectrum acquired from the elimination section 30 on a monitor. Through the spectrum analyzer 10 having the configuration described above, the frequency spectrum free of noise caused by the fractional spurious can be output.

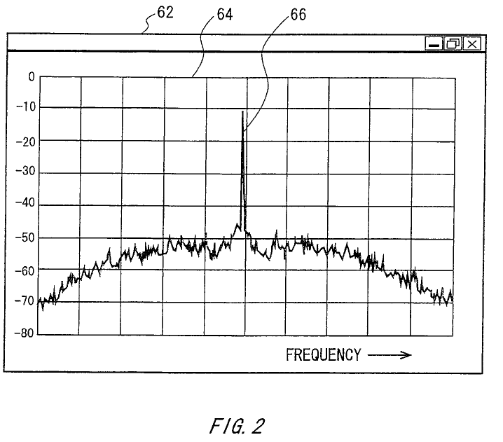

FIG. 2 shows an example of a measurement result output screen 62. For example, the output section 32 may display the measurement result output screen 62 on a monitor of a computer, thereby outputting a measurement result by the spectrum analyzer 10 to a user via the measurement result output screen 62. For example, the output section 32 may display the measurement result output screen 62 in which a graph 66 is plotted showing the frequency spectrum on a grid 64 where the frequency is represented by the X-axis and the signal level is represented by the Y-axis. Through the measurement result output screen 62 described above, the frequency spectrum free of noise caused by the fractional spurious can be displayed.

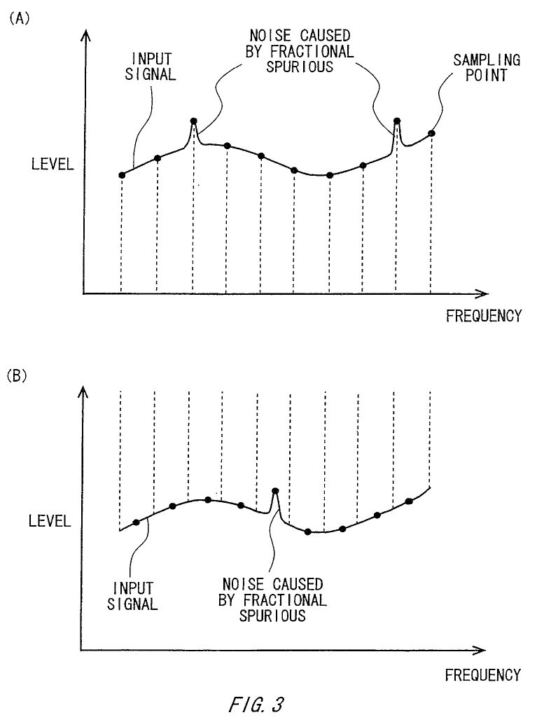

FIG. 3(A) shows an example of the first frequency spectrum. FIG. 3(B) shows an example of the second frequency spectrum. The first sweeping section 56 and the second sweeping section 58, by designating switching ratios different from each other to the fractional frequency divider 44, sweep the input signal with local frequencies different from each other generated from the oscillator 42. Accordingly, as shown in FIGS. 3(A) and 3(B), the first sweeping section 56 and the second sweeping section 58 generate the first frequency spectrum and the second frequency spectrum having frequencies of the input signal different from each other at corresponding sampling points. Therefore, the first sweeping section 56 and the second sweeping section 58 can generate the first frequency spectrum and the second frequency spectrum having frequencies in which the noise caused by the fractional spurious are generated that are different from each other.

For example, the elimination section 30 may generate the frequency spectrum free of noise caused by the fractional spurious by exchanging the signal component having a frequency including noise caused by the fractional spurious in the first frequency spectrum with the signal component having generally the same frequency in the second frequency spectrum.

Furthermore, for example, the spectrum generation section 28 may set the difference of the frequencies of corresponding sampling points in the first frequency spectrum and the second frequency spectrum to be a frequency difference within the pass band of the band-pass filter 24. In a case where the fractional spurious is large in one of the sampling points, it is preferable that the spectrum generation section 28 set a frequency difference having a relationship to decrease the fractional spurious in the other sampling point. The elimination section 30 may then compare the level of the sampling point in the first frequency spectrum to the level of the corresponding sampling point in the second frequency spectrum, select the value of the sampling point having the lower level, and generate the frequency spectrum based on the selected sampling point. Therefore, the elimination section 30 can easily generate the frequency spectrum free of noise caused by the fractional spurious.

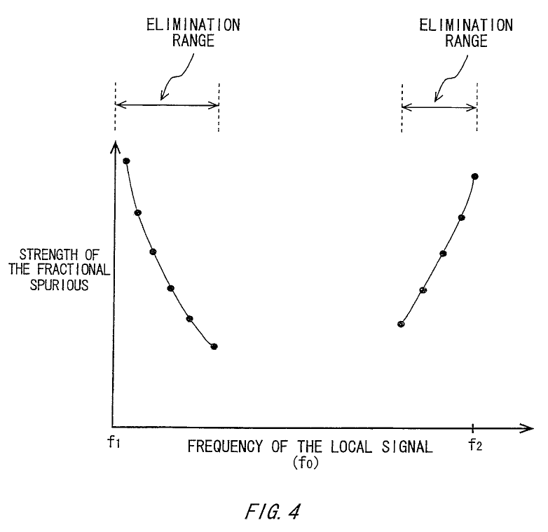

FIG. 4 shows a strength of the fractional spurious in the local signal and also shows a range of local frequencies free of the fractional spurious. In the present embodiment, the strength of the fractional spurious becomes larger as a frequency f₀ of the local signal approaches a first frequency f₁, which is a product of the reference frequency of the reference clock multiplied by the first frequency-dividing ratio. Furthermore, the strength of the fractional spurious becomes larger as the frequency f₀ of the local signal approaches a second frequency f₂, which is a product of the reference frequency of the reference clock multiplied by the second frequency-dividing ratio. In other words, the strength of the fractional spurious becomes smaller as the frequency f₀ of the local signal approaches an exact midpoint between the first frequency f₁ and the second frequency f₂, and the strength of the fractional spurious becomes larger as the frequency f₀ approaches either the first frequency f₁ or the second frequency f₂.

The elimination section 30 may designate the local signal to have a frequency set such that the frequency difference between the first frequency f₁ and the second frequency f₂ is less than or equal to a predetermined threshold value and perform a noise elimination process on the signal components of the input signal output from the band-pass filter 24. For example, the elimination section 30 may designate the local signal to have a frequency set such that the frequency difference between the first frequency f₁ and the second frequency f₂ is less than or equal to the predetermined threshold value stored in a register and then perform the noise elimination process. Therefore, the elimination section 30 can perform the noise elimination process on only the signal components having frequencies in which the fractional spurious is generated from among each frequency component of the frequency spectrum. Therefore, through the elimination section 30, the effective noise elimination process can be achieved.

Instead of the above, the elimination section 30 may designate frequencies of the local signal to be outside of a central frequency range, which is a range that is greater than or equal to a negative threshold frequency separated a prescribed amount in a negative direction from a midpoint frequency of the first frequency f₁ and the second frequency f₂ and less than or equal to a positive threshold frequency separated a prescribed amount in a positive direction from a midpoint frequency of the first frequency f₁ and the second frequency f₂, and perform the noise elimination process. In such a case, the distance between the negative threshold frequency and the midpoint frequency (the absolute value of the frequency) may be different from the distance between the positive threshold frequency and the midpoint frequency (the absolute value of the frequency).

Furthermore, the spectrum generation section 28 may set the local signal generating section to generate the local signal having a frequency such that the frequency difference between the first frequency f₁ and the second frequency f₂ is greater than the predetermined threshold value. By setting the local frequency such that the frequency difference between the first frequency f₁ and the second frequency f₂ is greater than the predetermined threshold value, the fractional spurious can be controlled even without performing the noise elimination process. In such a case, control of the fractional spurious is achieved through the first frequency spectrum acquired as a result of the frequency sweep by the first sweeping section 56.

Instead of the above, the spectrum generation section 28 may set the frequency of the local signal to be in a central frequency range, which is a range that is greater than or equal to a negative threshold frequency separated a prescribed amount in a negative direction from a midpoint frequency of the first frequency f₁ and the second frequency f₂ and less than or equal to a positive threshold frequency separated a prescribed amount in a positive direction from a midpoint frequency of the first frequency f₁ and the second frequency f₂. In such a case, the distance between the negative threshold frequency and the midpoint frequency (the absolute value of the frequency) may be different from the distance between the positive threshold frequency and the midpoint frequency (the absolute value of the frequency).

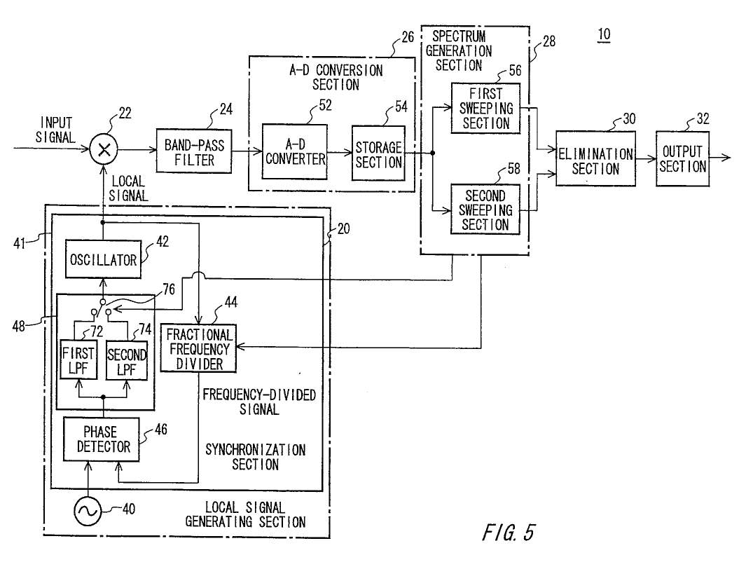

FIG. 5 shows a configuration of the spectrum analyzer 10 according to a first modification of the present embodiment. The spectrum analyzer 10 according to the first modification adopts generally the same configuration and functions as the spectrum analyzer 10 shown in FIG. 1, and therefore parts having a configuration and function generally the same as parts of FIG. 1 are given the same numbering as in FIG. 1 and, aside from the following differences, are omitted from the description.

In the first modification, the low-pass filter 48 low-pass filters the control signal output by the phase detector 46 with a first time constant or a second time constant, which is different from the first time constant, and outputs the low-pass filtered signal to the oscillator 42. For example, the low-pass filter 48 may include a first LPF 72 that low-pass filters the control signal output by the phase detector 46 with the first time constant, a second LPF 74 the low-pass filters the control signal output by the phase detector 46 with the second time constant, and a switching section 76 switching the output of the first LPF 72 and the second LPF 74 and outputting to the oscillator 42.

The low-pass filter 48 can further decrease the noise where the time constant of the low-pass filtering is increased. Accordingly, the low-pass filter 48 can increase and decrease the strength of the fractional spurious included in the local signal by switching the time constant of the low-pass filtering.

The first sweeping section 56 of the spectrum generation section 28 sets the time constant of the low-pass filter 48 to the first time constant, sequentially and discretely changes the frequency of the local signal, passes the signal component of each frequency within the measured frequency range of the input signal through the band-pass filter 24, and generates the first frequency spectrum based on the digital output signal acquired from the signal component passed through the band-pass filter 24. Furthermore, the second sweeping section 58 of the spectrum generation section 28 sets the time constant of the low-pass filter 48 to the second time constant, sequentially and discretely changes the frequency of the local signal, passes the signal component of each frequency within the measured frequency range of the input signal through the band-pass filter 24, and generates the second frequency spectrum based on the digital output signal acquired from the signal component passed through the band-pass filter 24. In addition to this, the second sweeping section 58 may sequentially and discretely change the frequency of the local signal with a switching ratio different from the switching ratio used during generation of the first frequency spectrum and pass the signal component of each frequency within the measured frequency range of the input signal through the band-pass filter 24.

The elimination section 30 then compares the first frequency spectrum to the second frequency spectrum, detects a frequency of a signal component changed to be greater than or equal to a predetermined amplitude based on the comparison result, and generates a frequency spectrum free of noise from the signal components near the detected frequency. Because the fractional spurious strength included in the local signal in the same frequency is different for the first frequency spectrum and the second frequency spectrum, the signal level of the frequency in which noise is generated by the fractional spurious changes. Accordingly, in a case where the comparison result is that the frequency is changed to be greater than or equal to the predetermined amplitude, the elimination section 30 may determine that the noise caused by the fractional spurious is included near the changed frequency and perform the process to eliminate the noise caused by the fractional spurious.

Therefore, the elimination section 30 according to the first modification can perform the process to eliminate noise on only the signal components having frequencies in which fractional spurious is generated from among each frequency component of the frequency spectrum. Accordingly, through the elimination section 30, the effective noise elimination process can be achieved.

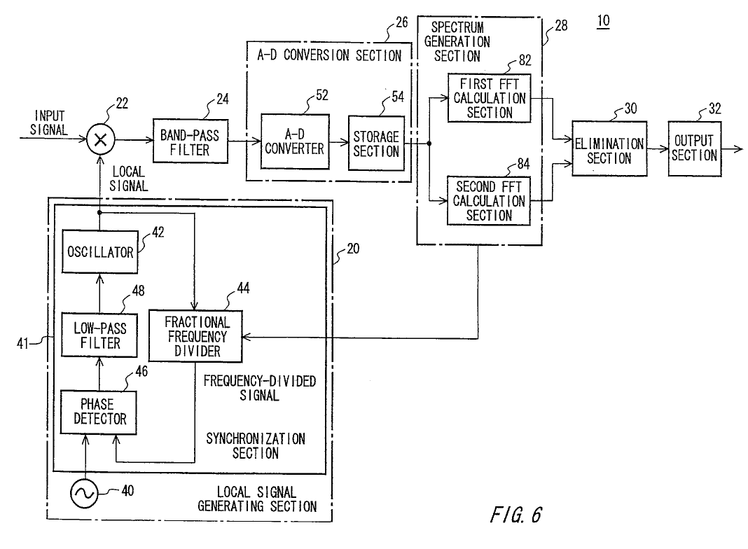

FIG. 6 shows a configuration of the spectrum analyzer 10 according to a second modification of the present embodiment. The spectrum analyzer 10 according to the second modification adopts generally the same configuration and functions as the spectrum analyzer 10 shown in FIG. 1, and therefore parts having a configuration and function generally the same as parts of FIG. 1 are given the same numbering as in FIG. 1 and, aside from the following differences, are omitted from the description.

The spectrum generation section 28 may include a first FFT calculation section 82 and a second FFT calculation section 84 instead of the first sweeping section 56 and the second sweeping section 58. The first FFT calculation section 82 controls the frequency of the local signal and passes the signal component within the measured frequency range in the input signal through the band-pass filter 24. The first FFT calculation section 82 then performs a Fourier transformation calculation (an FTT calculation, for example) on the digital output signal acquired from the signal component passed through the band-pass filter 24 and generates the first frequency spectrum. The second sweeping section 58 controls the frequency of the local signal to be different from the frequency during generation of the first frequency spectrum and passes the signal component within the measured frequency range in the input signal through the band-pass filter 24. The second FFT calculation section 84 then performs a Fourier transformation calculation (an FTT calculation, for example) on the digital output signal acquired from the signal component passed through the band-pass filter 24 and generates the second frequency spectrum.

Through the spectrum analyzer 10 according to the second modification as described above, the frequency spectrum can be generated by an FFT calculation. Therefore, through the spectrum analyzer 10, the frequency spectrum having a frequency resolution narrower than a pass band of the band-pass filter 24 can be generated.

Furthermore, in a case where a frequency spectrum having a frequency span wider than the pass band of the band-pass filter 24 is generated, the spectrum generation section 28 generates a plurality of divided ranges, which are divisions of the frequency span, for every pass band of the band-pass filter 24 or pass band narrower than the pass band of the band-pass filter 24. The spectrum generation section 28 sets each of the divided ranges among the plurality of divided ranges to be within a measured frequency range, sequentially controls the local frequencies to be frequencies corresponding to each of the divided ranges, and acquires a plurality of digital output signals from each of the divided ranges. The spectrum generation section 28 performs the FFT calculation for each of the digital output signals in the plurality of acquired digital output signals and generates a plurality of frequency spectrums. The spectrum generation section 28 then synthesizes the generated plurality of frequencies in a direction of the frequency.

Furthermore, in a case where the frequency is generated by the FFT calculation, the spectrum generation section 28 may set the local frequency to be in a place separated multiple IF frequencies from the central frequency of the measured frequency range. For example, the multiplying section 22 may contain two mixers. The first mixer down-converts the input signal to an IF signal of 421.4 MHz by multiplying the local signal output from the local signal generating section 20 with the input signal. The second mixer further down-converts the input signal to an IF signal of 21.4 MHz by multiplying the output signal of the first mixer with a sine wave of 400 MHz. Using the multiplying section 22 having the configuration described above, in a case where a frequency spectrum is generated in which the central frequency is 3 GHz and the frequency span is 8 MHz, the spectrum generation section 28 may set the frequency of the local signal to be 3.4214 GHz (=3 GHz+421.4 MHz) or 2.5786 GHz (=3 GHz−421.4 MHz).

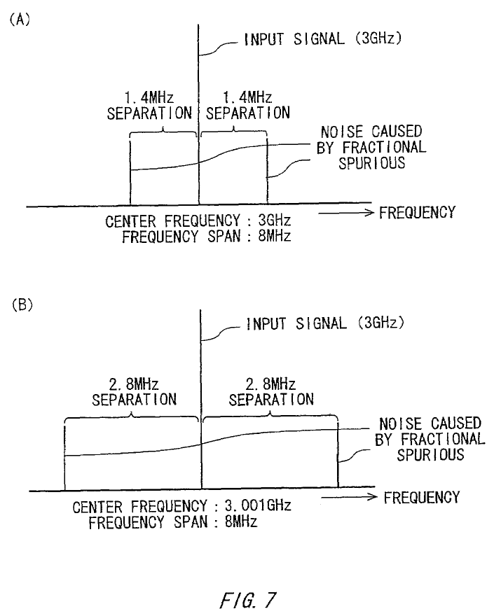

FIG. 7 shows an example of noise generated by the fractional spurious. In a case where the fractional frequency divider 44 is used, the noise generated by the fractional spurious is included in the frequency spectrum generated by the spectrum generation section 28 because the fractional spurious is superimposed on the local signal.

For example, using the multiplying section 22 having the configuration described above, in a case where the frequency spectrum is generated in which the central frequency is 3 GHz and the frequency span is 8 MHz, the spectrum generation section 28 may set the frequency-dividing ratio for the fractional frequency divider 44 to be (342+(573/4096)). In such a case, as shown in FIG. 7(A), the noise caused by the fractional spurious is included in the frequency spectrum at a place separated from the input signal by 1.4 MHz (=10 MHz×(573/4096)).

Here, after generating a first frequency spectrum such as that shown in FIG. 7(A), the spectrum generation section 28 generates a second frequency spectrum slightly out of alignment with the first frequency spectrum. For example, the spectrum generation section 28 may generate the second frequency spectrum in which the frequency of the local signal is increased 1 MHz higher than the frequency of the local signal during generation of the first frequency spectrum. In such a case, the central frequency becomes 3.001 GHz, the local frequency becomes 3.4224 GHz (=3.4214 GHz+1 MHz), and the frequency-dividing ratio set for the fractional frequency divider 44 becomes (342+(983/4096)). Accordingly, as shown in FIG. 7(B), the spectrum generation section 28 generates the frequency spectrum including the noise generated by the fractional spurious at a place separated from the input signal by 2.4 MHz (=10 MHz×(983/4096)).

The first frequency spectrum and the second frequency spectrum described above have frequency spans that are out of alignment with each other, but the frequency place of the input signal is the same 3 GHz for both. On the other hand, the first frequency spectrum and the second frequency spectrum have frequency places including the noise caused by the fractional spurious that are different from each other. Accordingly, the elimination section 30 can distinguish between the noise caused by the fractional spurious and the signal component of the input signal by comparing the first frequency spectrum to the second frequency spectrum.

For example, the elimination section 30 may generate a frequency spectrum in which the noise caused by the fractional spurious is removed by comparing signal components having the same frequency place in the first frequency spectrum and the second frequency spectrum and generating a new frequency spectrum using the signal component having the smaller value. In such a case, because the frequency span of the new frequency pattern generated by the elimination section 30 is shortened by only an amount of the misalignment with the local frequency, the spectrum generation section 28 may set the frequency span of the first frequency spectrum and the second frequency spectrum in advance to be as wide as the misalignment of the local signal.

In addition to eliminating the fractional spurious, the elimination section 30 may generate a frequency spectrum in which noise caused by mixing of the signal passed through the band-pass filter 24 and changing of the frequency according to change of the local signal is eliminated by comparing the first frequency spectrum to the second frequency spectrum. For example, the elimination section 30 may generate a frequency spectrum in which the signal passed through the band-pass filter 24 and mixed by the operational clock of the circuit is eliminated. For example, by mixing a 25 MHz operational clock with a 21.4 MHz IF signal, a frequency spectrum including noise of 3.6 MHz is generated. The frequency of said noise changes according to a change of the frequency of the local signal because the frequency of the IF signal changes according to a change of the frequency of the local signal. The elimination section 30 may generate a frequency spectrum free of both the aforementioned noise and the noise caused by the fractional spurious.

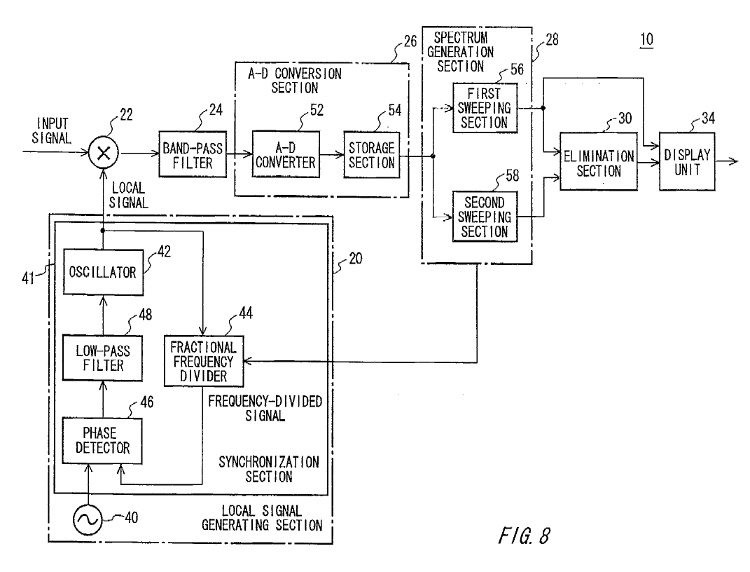

FIG. 8 shows a configuration of the spectrum analyzer 10 according to a third modification of the present embodiment. The spectrum analyzer 10 according to the third modification adopts generally the same configuration and functions as the spectrum analyzer 10 shown in FIG. 1, and therefore parts having a configuration and function generally the same as parts of FIG. 1 are given the same numbering as in FIG. 1 and, aside from the following differences, are omitted from the description.

The spectrum analyzer 10 according to the third modification is provided with a display section 34 instead of the output section 32. After the first frequency spectrum is generated by the spectrum generation section 28, the display section 34 acquires and displays the first frequency spectrum from the spectrum generation section 28 while the noise elimination is being completed by the elimination section 30. The display section 34 then acquires and displays the frequency spectrum free of noise from the elimination section 30 when the elimination section 30 has completed the noise elimination.

Through the spectrum analyzer 10 having the configuration described above, a frequency spectrum free of noise can be output. Furthermore, through the spectrum analyzer 10 having the configuration described above, a measurement result of a progression of the noise elimination process can be displayed even where the noise elimination process requires a long time period.

The elimination section 30 is not limited to eliminating the noise caused by the fractional spurious and may eliminate other types of noise. In such a case, the display section 34 may acquire and display the first frequency spectrum before the noise is eliminated from the spectrum generation section 28 while the noise elimination is being completed by the elimination section 30 and may also acquire and display the frequency spectrum free of noise when the elimination section 30 has completed the noise elimination.

For example, the elimination section 30 may eliminate noise included in double the frequency of the central frequency (intermediate frequency) of the signal component output from the multiplying section 22. In such a case, the elimination section 30 selects the lowest spectral value from among the spectral values of each frequency and two spectral values obtained by adding or subtracting double the frequency of the intermediate frequency to the frequency in the frequency spectrum generated by the spectrum generation section 28. The elimination section 30 may then eliminate the noise by setting the selected spectral value to be the spectral value of each frequency in the frequency spectrum generated by the spectrum generation section 28. Furthermore, in a case where a higher harmonic component of the local signal is included in the synthesized signal output from the multiplying section 22, the elimination section 30 may execute a process to remove the higher harmonic portion.

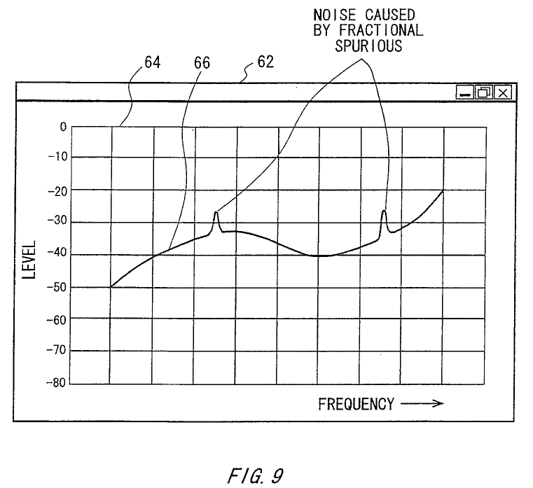

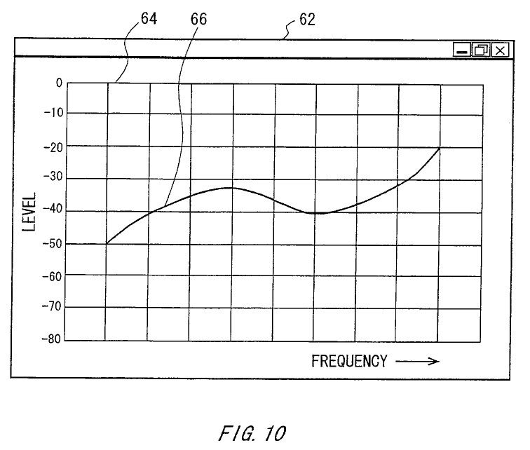

FIG. 9 shows an example of the measurement result output screen 62 before noise elimination. FIG. 10 shows an example of the measurement result output screen 62 after noise elimination. For example, the display section 34 may display the measurement result output screen 62 on the monitor of the computer, thereby outputting the measurement result by the spectrum analyzer 10 to a user via the measurement result output screen 62. For example, the display section 34 may display the measurement result output screen 62 in which a graph 66 is plotted showing the frequency spectrum on a grid 64 where the frequency is represented by the X-axis and the signal level is represented by the Y-axis.

Upon initiation of the measurement process, the spectrum generation section 28 generates the first frequency spectrum. Then, after the first frequency spectrum is generated by the spectrum generation section 28, the display section 34 acquires and displays the first frequency spectrum, such as that shown in FIG. 9, from the spectrum generation section 28 while the elimination section 30 is completing the noise elimination.

Upon completion of the generation of the first frequency spectrum, the spectrum generation section 28 generates the second frequency spectrum. Upon generation of the second frequency spectrum, the elimination section 30 generates the frequency spectrum free of noise based on the first frequency spectrum and the second frequency spectrum. The display section 34 then displays the frequency spectrum free of noise, such as that displayed in FIG. 10, when noise elimination by the elimination section 30 is completed. Furthermore, the display section 34 may display a portion on which the noise elimination process is performed in a manner to be distinguishable from a portion on which the noise elimination process is not performed. Through the display section 34 having the configuration described above, the measurement result of a progression of the noise elimination process can be displayed.

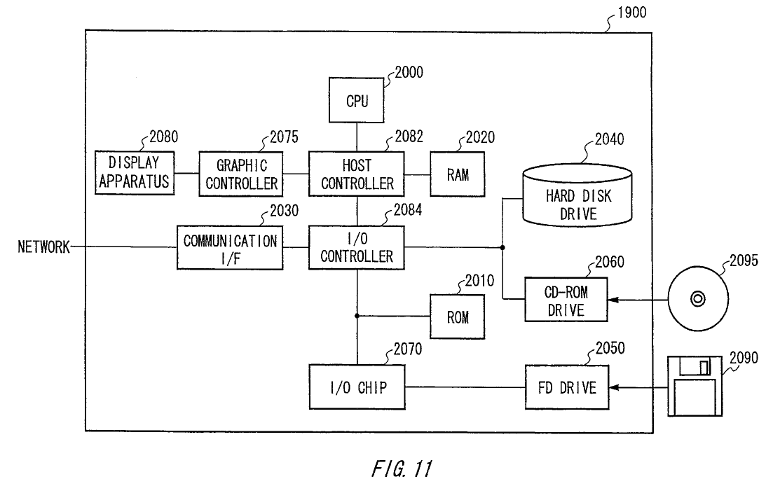

FIG. 11 shows an example of a hardware configuration of a computer 1900 according to the present embodiment. The computer 1900 according to the present embodiment is provided with a CPU peripheral including a CPU 2000, a RAM 2020, a graphic controller 2075, and a displaying apparatus 2080, all of which are connected to each other by a host controller 2082; an input/output section including a communication interface 2030, a hard disk drive 2040, and a CD-ROM drive 2060, all of which are connected to the host controller 2082 by an input/output controller 2084; and a legacy input/output section including a ROM 2010, a flexible disk drive 2050, and an input/output chip 2070, all of which are connected to the input/output controller 2084.

The host controller 2082 is connected to the RAM 2020 and is also connected to the CPU 2000 and graphic controller 2075 accessing the RAM 2020 at a high transfer rate. The CPU 2000 operates to control each section based on programs stored in the ROM 2010 and the RAM 2020. The graphic controller 2075 acquires image data generated by the CPU 2000 or the like on a frame buffer disposed inside the RAM 2020 and displays the image data in the displaying apparatus 2080. In addition, the graphic controller 2075 may internally include the frame buffer storing the image data generated by the CPU 2000 or the like.

The input/output controller 2084 connects the communication interface 2030 serving as a relatively high speed input/output apparatus, the hard disk drive 2040, and the CD-ROM drive 2060 to the host controller 2082. The communication interface 2030 communicates with other apparatuses via a network. The hard disk drive 2040 stores the programs and data used by the CPU 2000 housed in the computer 1900. The CD-ROM drive 2060 reads the programs and data from a CD-ROM 2095 and provides the read information to the hard disk drive 2040 via the RAM 2020.

Furthermore, the input/output controller 2084 is connected to the ROM 2010, and is also connected to the flexible disk drive 2050 and the input/output chip 2070 serving as a relatively high speed input/output apparatus. The ROM 2010 stores a boot program performed when the computer 1900 starts up, a program relying on the hardware of the computer 1900, and the like. The flexible disk drive 2050 reads programs or data from a flexible disk 2090 and supplies the read information to the hard disk drive 2040 via the RAM 2020. The input/output chip 2070 connects the flexible disk drive 2050 to each of the input/output apparatuses via, for example, a parallel port, a serial port, a keyboard port, a mouse port, or the like.

The programs provided to the hard disk drive 2040 via the RAM 2020 are stored in a storage medium, such as the flexible disk 2090, the CD-ROM 2095, or an IC card, and provided by a user. The programs are read from storage medium, installed in the hard disk drive 2040 inside the computer 1900 via the RAM 2020, and performed by the CPU 2000.

The programs installed in the computer 1900 to make the computer 1900 function as a control apparatus of the spectrum analyzer 10 are provided with a local signal generation module, a multiplication module, a band-pass filter module, an A-D conversion module, a spectrum generation module, an elimination module, and an output module. Furthermore, the above programs may be provided with a display module instead of the output module. These programs and modules prompt the CPU 2000 or the like to make the computer 1900 function as the spectrum analyzer 10, the local signal generating section 20, the multiplying section 22, the band-pass filter 24, the A-D conversion section 26, the spectrum generation section 28, the elimination section 30, the output section 32, and the display section 34, respectively.

The programs and modules shown above may also be stored in an external storage medium. The flexible disk 2090, the CD-ROM 2095, an optical storage medium such as a DVD or CD, a magneto-optical storage medium, a tape medium, a semiconductor memory such as an IC card, or the like can be used as the storage medium. Furthermore, a storage apparatus such as a hard disk or RAM that is provided with a server system connected to the Internet or a specialized communication network may be used to provide the programs to the computer 1900 via the network.

While the embodiment of the present invention has been described, the technical scope of the invention is not limited to the above described embodiment. It is apparent to persons skilled in the art that various alterations and improvements can be added to the above-described embodiment. It is also apparent from the scope of the claims that the embodiments added with such alterations or improvements can be included in the technical scope of the invention.

What is claimed is:

1. A spectrum analyzer that measures a signal component for every frequency of an input signal, comprising:
a local signal generating section that generates a local signal having a designated frequency;
a multiplying section that outputs a synthesized signal obtained by multiplying the local signal with the input signal;
a band-pass filter through which a signal component having a prescribed frequency band of the synthesized signal is passed;
an A-D conversion section that outputs a digital output signal obtained by sampling and digitalizing the signal component passed through the band-pass filter;
a spectrum generation section that passes a signal component within a measured frequency range of the input signal through the band-pass filter and generates a first frequency spectrum based on the digital output signal acquired from the signal component passed through the band-pass filter; and
an elimination section that generates a frequency spectrum free of noise based on the first frequency spectrum generated by the spectrum generation section.

2. The spectrum analyzer according to claim 1, wherein:
the local signal generating section is provided with a synchronization section that outputs a local signal having a local frequency obtained by multiplying a reference frequency of a reference clock by a factor having fractional precision;
the spectrum generation section controls the local frequency of the local signal, passes the signal component within the measured frequency range of the input signal through the band-pass filter, generates the first frequency spectrum based on the digital output signal acquired from the signal component passed through the band-pass filter, controls the local frequency to be different from the local frequency during generation of the first frequency spectrum, passes the signal component within the measured frequency range of the input signal through the band-pass filter, and generates a second frequency spectrum based on the digital output signal acquired from the signal component passed through the band-pass filter; and
the elimination section generates a frequency spectrum free of noise based on the first frequency spectrum and the second frequency spectrum.

3. The spectrum analyzer according to claim 2, wherein the spectrum generation section discretely and sequentially changes the local frequency of the local signal, passes the signal component within the measured frequency range of the input signal through the band-pass filter, and generates a frequency spectrum based on the digital output signal acquired from the signal component passed through the band-pass filter.

4. The spectrum analyzer according to claim 2, wherein the spectrum generation section generates a frequency spectrum by Fourier transforming the digital output signal acquired from the signal component passed through the band-pass filter.

5. The spectrum analyzer according to claim 2, wherein the elimination section generates a frequency spectrum free of noise based on a smaller value from among signal components having generally identical frequencies in the first frequency spectrum and the second frequency spectrum.

6. The spectrum analyzer according to claim 2, wherein the synchronization section includes:
an oscillator that generates a local signal having a frequency according to a control signal;
a frequency divider that sets a switching ratio for switching between a period of frequency-dividing with a first frequency-dividing ratio having an integer value and a period of frequency-dividing with a second frequency-dividing ratio having an integer value according to the frequency of the local signal and outputs a frequency-divided signal obtained by frequency-dividing the local signal while switching between the first frequency-dividing ratio and the second frequency-dividing ratio according to the switching ratio; and
a phase detector that outputs the control signal according to a phase difference between the frequency-divided signal and a reference clock.

7. The spectrum analyzer according to claim 6, wherein the elimination section generates a frequency spectrum free of noise caused by fractional spurious, which is generated at a frequency determined by a difference between the first frequency and the frequency of the local signal, by comparing the first frequency spectrum to the second frequency spectrum.

8. The spectrum analyzer according to claim 6, wherein the elimination section performs a process to eliminate noise from the signal component of the input signal output from the band-pass filter by setting a local signal to have a frequency such that a frequency difference between a first frequency, which is obtained by multiplying the reference frequency of the reference clock with the first frequency-dividing ratio, and a second frequency, which is obtained by multiplying the reference frequency with the second frequency-dividing ratio, is less than or equal to a predetermined threshold value.

9. The spectrum analyzer according to claim 6, wherein:
the synchronization section further includes a low-pass filter that low-pass filters the control signal output by the phase detector with a first time constant or with a second time constant that is different from the first time constant and outputs the low-pass filtered signal to the oscillator;
the spectrum generation section sets the time constant of the low-pass filter to be the first time constant during generation of the first frequency spectrum and sets the time constant of the low-pass filter to be the second time constant during generation of the second frequency spectrum; and
the elimination section compares the first frequency spectrum to the second frequency spectrum, detects a frequency of a signal component changed to be greater than or equal to a predetermined amplitude based on the comparison result, and generates a frequency spectrum free of noise from a signal component near the detected frequency.

10. The spectrum analyzer according to claim 2, wherein the elimination section generates a frequency spectrum in which noise caused by mixing of the signal passed through the band-pass filter and changing of the frequency according to change of the local signal is eliminated by comparing the first frequency spectrum to the second frequency spectrum.

11. The spectrum analyzer according to claim 1, further comprising:
a frequency divider that sets a switching ratio for switching between a period of frequency-dividing with a first frequency-dividing ratio having an integer value and a period of frequency-dividing with a second frequency-dividing ratio having an integer value according to the frequency of the local signal and outputs a frequency-divided signal obtained by frequency-dividing the local signal while switching between the first frequency-dividing ratio and the second frequency-dividing ratio according to the switching ratio;
a phase detector that outputs the control signal according to a phase difference between the frequency-divided signal and a reference clock; and
a low-pass filter that low-pass filters the control signal output by the phase detector with a first time constant or with a second time constant that is different from the first time constant and outputs the low-pass filtered signal to an oscillator included in the local signal generating section, and wherein:
the oscillator generates a local signal having a frequency according to a control signal;
the spectrum generation section sets the time constant of the low-pass filter to be the first time constant, discretely and sequentially changes the local frequency of the local signal, passes the signal component within the measured frequency range of the input signal through the band-pass filter, generates a first frequency spectrum based on the digital output signal acquired from the signal component passed through the band-pass filter sets the time constant of the low-pass filter to be the second time constant, discretely and sequentially changes the local frequency of the local signal, passes the signal component within the measured frequency range of the input signal through the band-pass filter, and generates a second frequency spectrum based on the digital output signal acquired from the signal component passed through the band-pass filter; and
the elimination section compares the first frequency spectrum to the second frequency spectrum, detects a frequency of a signal component changed to be greater than or equal to a predetermined amplitude based on the comparison result, and generates a frequency spectrum free of noise from a signal component near the detected frequency.

12. A spectrum analysis method that measures a signal component for every frequency of an input signal using a spectrum analyzer, comprising:
generating a local signal having a designated frequency;
outputting a synthesized signal obtained by multiplying the local signal with the input signal;
passing a signal component having a prescribed frequency band of the synthesized signal;
outputting a digital output signal obtained by sampling and digitalizing the passed signal component;
passing a signal component within a measured frequency range of the input signal and generating a first frequency spectrum based on the digital output signal acquired from the passed signal component; and
generating a frequency spectrum free of noise based on the generated first frequency spectrum.

13. The spectrum analysis method according to claim 12, wherein:
during a stage at which a local signal is generated, a local signal having a local frequency obtained by multiplying a reference frequency of a reference clock by a factor having fractional precision is output;
during a stage at which a first frequency spectrum is generated, the local frequency of the local signal is controlled, the signal component within the measured frequency range of the input signal is passed, and the first frequency spectrum is generated based on the digital output signal acquired from the passed signal component;
furthermore, the local frequency is controlled to be different from the local frequency during generation of the first frequency spectrum, the signal component within the measured frequency range of the input signal is passed, and a second frequency spectrum is generated based on the digital output signal acquired from the passed signal component; and
during a stage at which a frequency spectrum free of noise is generated, a frequency spectrum free of noise is generated based on the first frequency spectrum and the second frequency spectrum.

14. The spectrum analysis method according to claim 12, wherein:
during a stage at which a local signal is generated, a local signal having a frequency according to a control signal is generated;
a switching ratio for switching between a period of frequency-dividing with a first frequency-dividing ratio having an integer value and a period of frequency-dividing with a second frequency-dividing ratio having an integer value is set according to the frequency of the local signal and a frequency-divided signal obtained by frequency-dividing the local signal while switching between the first frequency-dividing ratio and the second frequency-dividing ratio according to the switching ratio is output;
the control signal according to a phase difference between the frequency-divided signal and a reference clock is output;
during a stage at which the local signal is generated, the control signal is low-pass filtered with a first time constant or a second time constant, which is different from the first time constant, and then output;
during a stage at which a first frequency spectrum is generated, the time constant of the low-pass filtering is set to be the first time constant, the frequency of the local signal is discretely and sequentially changed, the signal component within the measured frequency range of the input signal is passed, and the first frequency spectrum is generated based on the digital output signal acquired from the passed signal component;
the time constant of the low-pass filtering is set to be the second time constant, the frequency of the local signal is discretely and sequentially changed, the signal component within the measured frequency range of the input signal is passed, and a second frequency spectrum is generated based on the digital output signal acquired from the passed signal component; and
during a stage at which a frequency spectrum free of noise is generated, the first frequency spectrum is compared to the second frequency spectrum, a frequency of a signal component changed to be greater than or equal to a predetermined amplitude based on the comparison result is detected, and a frequency spectrum free of noise from a signal component near the detected frequency is generated.

15. A recording medium that stores thereon a program controlling through a computer a spectrum analyzer that measures a signal component for every frequency of an input signal, the program causing the spectrum analyzer to function as:
a local signal generating section that generates a local signal having a designated frequency;
a multiplying section that outputs a synthesized signal obtained by multiplying the local signal with the input signal;
a band-pass filter through which a signal component having a prescribed frequency band of the synthesized signal is passed;
an A-D conversion section that outputs a digital output signal obtained by sampling and digitalizing the signal component passed through the band-pass filter;
a spectrum generation section that passes a signal component within a measured frequency range of the input signal through the band-pass filter and generates a first frequency spectrum based on the digital output signal acquired from the signal component passed through the band-pass filter; and
an elimination section that generates a frequency spectrum free of noise based on the first frequency spectrum generated by the spectrum generation section.

16. The recording medium according to claim 15, wherein:
the local signal generating section is provided with a synchronization section that outputs a local signal having a local frequency obtained by multiplying a reference frequency of a reference clock by a factor having fractional precision;
the spectrum generation section controls the local frequency of the local signal, passes the signal component within the measured frequency range of the input signal through the band-pass filter, generates the first frequency spectrum based on the digital output signal acquired from the signal component passed through the band-pass filter, controls the local frequency to be different from the local frequency during generation of the first frequency spectrum, passes the signal component within the measured frequency range of the input signal through the band-pass filter, and generates a second frequency spectrum based on the digital output signal acquired from the signal component passed through the band-pass filter; and
the elimination section 30 generates a frequency spectrum free of noise based on the first frequency spectrum and the second frequency spectrum.

17. The recording medium according to claim 15, wherein:
the program makes the spectrum analyzer further function as:
a frequency divider that sets a switching ratio for switching between a period of frequency-dividing with a first frequency-dividing ratio having an integer value and a period of frequency-dividing with a second frequency-dividing ratio having an integer value according to the frequency of the local signal and outputs a frequency-divided signal obtained by frequency-dividing the local signal while switching between the first frequency-dividing ratio and the second frequency-dividing ratio according to the switching ratio;
a phase detector that outputs the control signal according to a phase difference between the frequency-divided signal and a reference clock; and
a low-pass filter that low-pass filters the control signal output by the phase detector with a first time constant or with a second time constant that is different from the first time constant and outputs the low-pass filtered signal to an oscillator included in the local signal generating section;
the oscillator generates a local signal having a frequency according to a control signal;
the spectrum generation section sets the time constant of the low-pass filter to be the first time constant, discretely and sequentially changes the local frequency of the local signal, passes the signal component within the measured frequency range of the input signal through the band-pass filter, generates the first frequency spectrum based on the digital output signal acquired from the signal component passed through the band-pass filter sets the time constant of the low-pass filter to be the second time constant, discretely and sequentially changes the local frequency of the local signal, passes the signal component within the measured frequency range of the input signal through the band-pass filter, and generates a second frequency spectrum based on the digital output signal acquired from the signal component passed through the band-pass filter; and
the elimination section compares the first frequency spectrum to the second frequency spectrum, detects a frequency of a signal component changed to be greater than or equal to a predetermined amplitude based on the comparison result, and generates a frequency spectrum free of noise from a signal component near the detected frequency.

18. The spectrum analyzer according to claim 1, further comprising a display section that, after the generation of the first frequency spectrum by the spectrum generation section is completed, displays the first frequency spectrum while the elimination section is completing noise elimination and displays the frequency spectrum free of noise as the noise elimination is completed by the elimination section.

19. The spectrum analyzer according to claim 18, wherein:
the spectrum generation section, after generation of the first frequency spectrum, passes the signal component within the measured frequency range of the input signal through the band-pass filter and generates a second frequency spectrum based on the digital output signal acquired from the signal component passed through the band-pass filter; and
the elimination section generates the frequency spectrum free of noise based on the first frequency spectrum and the second frequency spectrum.

20. The spectrum analyzer according to claim 19, wherein:
the local signal generating section includes a synchronization section that outputs a local signal having a local frequency obtained by multiplying a reference frequency of a reference clock by a factor having fractional precision;
the spectrum generation section controls the local frequency of the local signal, passes the signal component within the measured frequency range of the input signal through the band-pass filter, generates the first frequency spectrum based on the digital output signal acquired from the signal component passed through the band-pass filter, controls the local frequency to be different from the local frequency during generation of the first frequency spectrum, passes the signal component within the measured frequency range of the input signal through the band-pass filter, and generates a second frequency spectrum based on the digital output signal acquired from the signal component passed through the band-pass filter.

21. The spectrum analysis method according to claim 12, wherein, after the generation of the first frequency spectrum is completed through the step at which the first frequency spectrum is generated, the first frequency spectrum is displayed while noise elimination is being completed during a step at which noise is eliminated from the first frequency spectrum and the frequency spectrum free of noise is displayed as the noise elimination is completed during a stage at which the frequency spectrum free of noise is generated.

22. The recording medium according to claim 15, wherein the program makes the spectrum analyzer further function as a display section that, after the generation of the first frequency spectrum by the spectrum generation section is completed, displays the first frequency spectrum while the elimination section is completing noise elimination and displays the frequency spectrum free of noise as the noise elimination is completed by the elimination section.

23. A spectrum analyzer that measures a signal component for every frequency of an input signal, comprising:
a local signal generating section that generates a local signal having a designated frequency;
a multiplying section that outputs a synthesized signal obtained by multiplying the local signal with the input signal;
a band-pass filter through which a signal component having a prescribed frequency band of the synthesized signal is passed;
an A-D conversion section that outputs a digital output signal obtained by sampling and digitalizing the signal component passed through the band-pass filter; and
a spectrum generation section that passes a signal component within a measured frequency range of the input signal through the band-pass filter and generates a first frequency spectrum based on the digital output signal acquired from the signal component passed through the band-pass filter, and wherein:
the local signal generating section includes:
an oscillator that generates a local signal having a frequency according to a control signal;
a frequency divider that sets a switching ratio for switching between a period of frequency-dividing with a first frequency-dividing ratio having an integer value and a period of frequency-dividing with a second frequency-dividing ratio having an integer value according to the frequency of the local signal and outputs a frequency-divided signal obtained by frequency-dividing the local signal while switching between the first frequency-dividing ratio and the second frequency-dividing ratio according to the switching ratio; and
a phase detector that outputs the control signal according to a phase difference between the frequency-divided signal and a reference clock; and
the spectrum generation section is provided with a local signal generating section configured in a manner to generate a local signal having a frequency such that the frequency difference between a first frequency, which is obtained by multiplying the reference frequency of the reference clock with the first frequency-dividing ratio, and a second frequency, which is obtained by multiplying the reference frequency with the second frequency-dividing ratio, is not less than or equal to a predetermined threshold value.
